(19) United States
(12) Patent Application Publication
(10) Pub. No.: US 2023/0135418 A1
(43) Pub. Date: May 4, 2023

(54) FUSE STRUCTURE, METHOD FOR MANUFACTURING SAME AND PROGRAMMABLE MEMORY

(71) Applicant: CHANGXIN MEMORY TECHNOLOGIES, INC., Hefei City (CN)

(72) Inventor: CHIH-CHENG LIU, Hefei City (CN)

(73) Assignee: CHANGXIN MEMORY TECHNOLOGIES, INC., Hefei City (CN)

(21) Appl. No.: 17/806,251

(22) Filed: Jun. 9, 2022

Related U.S. Application Data
(63) Continuation of application No. PCT/CN2022/076300, filed on Feb. 15, 2022.

(30) Foreign Application Priority Data
Nov. 3, 2021 (CN) 202111296012.X

(51) Int. Cl. H01L 27/112; H01L 23/525; G11C 17/16

(52) U.S. Cl. CPC H01L 27/11206; H01L 23/5252; H01L 23/5256; G11C 17/165

(57) ABSTRACT

A fuse structure includes a gate structure, a first electrode, a second electrode and an isolation structure. The gate structure is at least partially formed on an active area of a substrate. The first electrode is formed on the active area of the substrate and spaced apart from the gate structure. The second electrode is formed at least on a side of the gate structure. The isolation structure is formed between the active area and the second electrode.

### CROSS-REFERENCE TO RELATED APPLICATIONS

This is a continuation application of International Patent Application No. PCT/CN2022/076300 filed on Feb. 15, 2022, which claims priority to Chinese Patent Application No. 202111296012.X filed on Nov. 3, 2021. The disclosures of these applications are hereby incorporated by reference in their entirety.

### BACKGROUND

A one time programmable (OTP) memory is classified into a fuse type and an anti-fuse type, in which a programmable unit of the anti-fuse type memory is an anti-fuse structure. The anti-fuse structure specifically includes a fuse dielectric layer and two electrodes connected to both sides of the fuse dielectric layer, respectively. When not programmed, a voltage applied to the fuse dielectric layer is low, and the fuse dielectric layer is not broken down. At this time, the anti-fuse structure is equivalent to a capacitor, and presents a high-resistance state. When programmed, the voltage is increased to break down the fuse dielectric layer. At this time, the anti-fuse structure is equivalent to a resistor, and presents a low-resistance state.

However, in order to tune a work function, the oxide layer of the gate structure in the memory is usually thick, which makes the fuse dielectric layer difficult to be broken down.

### SUMMARY

Embodiments of the disclosure relate to, but are not limited to, a fuse structure, a method for manufacturing the same and a programmable memory.

A first aspect of embodiments of the present disclosure provides a fuse structure including a gate structure, a first electrode, a second electrode, and an isolation structure.

The gate structure is at least partially formed on the active area of the substrate.

The first electrode is formed on the active area of the substrate, and is spaced apart from the gate structure.

The second electrode is formed at least on a side of the gate structure.

The isolation structure is formed between the active area and the second electrode.

A second aspect of embodiments of the present disclosure provides a method for forming a fuse structure including the following operations.

A substrate is provided, in which the substrate comprises an active area and an isolation structure adjoining the active area.

A gate structure is formed, in which the gate structure is at least partially formed on the active area.

A first electrode is formed, in which the first electrode is formed on the active area, and is spaced apart from the gate structure.

A second electrode is formed, in which the second electrode is at least partially formed on the isolation structure and adjoins a side of the gate structure.

### BRIEF DESCRIPTION OF THE DRAWINGS

FIG. 1 is a structural schematic diagram of a fuse structure provided according to an embodiment of the present disclosure;

FIG. 2 is a first schematic diagram of procedures for forming a fuse structure according to an embodiment of the present disclosure.

FIG. 3 is a second schematic diagram of procedures for forming a fuse structure according to an embodiment of the present disclosure.

FIG. 4 is a third schematic diagram of procedures for forming a fuse structure according to an embodiment of the present disclosure.

FIG. 5 is a fourth schematic diagram of procedures for forming a fuse structure according to an embodiment of the present disclosure.

FIG. 6 is a fifth schematic diagram of procedures for forming a fuse structure according to an embodiment of the present disclosure.

FIG. 7 is a sixth schematic diagram of procedures for forming a fuse structure according to an embodiment of the present disclosure.

FIG. 8 is a seventh schematic diagram of procedures for forming a fuse structure according to an embodiment of the present disclosure.

### DETAILED DESCRIPTION

In order to make the purpose, technical solutions and advantages of the embodiments of the present disclosure clearer, the embodiments of the present disclosure are further described in detail below with reference to the detailed description and accompanying drawings. It should be understood that these descriptions are only exemplary, and are not intended to limit the scope of the embodiments of the disclosure. In addition, in the following descriptions, descriptions of well-known structures and technologies are omitted to avoid unnecessarily confusing the concepts of the embodiments of the present disclosure.

In the descriptions of the embodiments of the present disclosure, it is to be noted that terms “first” and “second” are only used for descriptive purposes, and should not be understood as indicating or implying a relative importance.

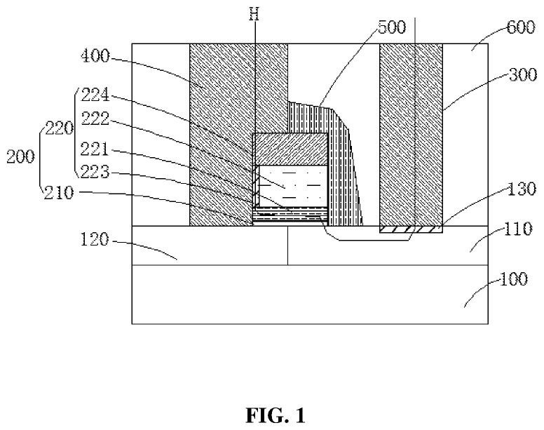

Referring to FIG. 1, an embodiment of the present disclosure provides a fuse structure including a gate structure 200, a first electrode 300, a second electrode 400 and an isolation structure 120.

The gate structure 200 is at least partially formed on an active area 110 of the substrate 100.

The first electrode 300 is formed on the active area 110 of the substrate 100, and is spaced apart from the gate structure 200.

The second electrode 400 is formed at least on a side of the gate structure 200.

The isolation structure 120 is formed between the active area 110 and the second electrode 400.

In the fuse structure of the embodiment, in a direction from the first electrode 300 to the second electrode 400, the first electrode 300, the active area 110, the gate structure 200 and the second electrode 400 are electrically connected in sequence to form an electrical path H. By connecting the second electrode 400 to the side of the gate structure 200, a contact area between the second electrode 400 and the gate structure 200 can be increased, which helps to reduce the conductive resistance, increasing the current in the electrical path H. As a result, it is easier to break down the fuse dielectric layer 210 of the gate structure 200.

In some embodiments, the substrate 100 may be a P-type silicon substrate or an N-type silicon substrate. In the embodiment, the substrate 100 is a P-type silicon substrate.

In some embodiments, the substrate 100 may be a monocrystalline silicon substrate or a polysilicon substrate. In the embodiment, the substrate 100 is a polysilicon substrate. The material of the active area 110 formed in the substrate 100 may be polysilicon.

In some embodiments, the material of the first electrode 300 and the second electrode 400 may be one or more of tungsten (W), cobalt (Co), nickel (Ni), tantalum (Ta), tantalum nitride (TaN), titanium (Ti), titanium nitride (TiN), etc. For example, the material of the first electrode 300 and the second electrode 400 each is titanium nitride.

In some embodiments, in order to reduce the interaction between the first electrode 300 and the second electrode 400, the fuse structure further includes a passivation layer 600.

The passivation layer 600 is formed between the first electrode 300 and the second electrode 400.

Exemplarily, the passivation layer 600 includes an insulating material with an isolation function. For example, the passivation layer 600 may be an oxide layer (BOX), and the material of the oxide layer may be silicon oxide (SiO₂).

In some embodiments, the isolation structure 120 may be an isolation structure formed on a surface of the substrate 100, or a shallow trench isolation (STI) formed in the substrate 100.

Exemplarily, the isolation structure 120 is formed in the substrate 100 and adjoins the active area 110. The second electrode 400 is formed on the isolation structure 120.

Exemplarily, the gate structure 200 is formed on both the active area 110 and the isolation structure 120.

In some embodiments, the gate structure 200 includes a fuse dielectric layer 210 and a gate material layer 220.

The fuse dielectric layer 210 is used for being broken down by a programming current.

The gate material layer 220 is formed on the fuse dielectric layer 210.

Exemplarily, the fuse dielectric layer 210 of the gate structure 200 serves as a gate dielectric layer of the gate structure 200, and the material of the fuse dielectric layer 210 may be hafnium oxide (HfO₂). Adopting HfO₂ as the gate dielectric layer can allow the thickness of the gate dielectric layer to be smaller, thereby further reducing the difficulty in being broken down. In some embodiments, an equivalent thickness of HfO₂ may be less than 25 angstroms. For example, that the equivalent thickness of the fuse dielectric layer 210 may be 15 angstroms, 16 angstroms, 17 angstroms, 18 angstroms, 19 angstroms or 20 angstroms, etc.

Exemplarily, the gate material layer 220 includes a second conductive layer 222, a first metal layer 221 and a second metal layer 224. The first metal layer 221 is provided between the second conductive layer 222 and the fuse dielectric layer 210, and the second metal layer 224 is provided between the second conductive layer 222 and the second electrode 400.

In some embodiments, the material of the second conductive layer 222 may be polysilicon. The thickness of the second conductive layer 222 may be 300-700 angstroms. For example, the thickness of the dielectric layer 222 may be 300 angstroms, 400 angstroms, 500 angstroms, 600 angstroms or 700 angstroms.

In some embodiments, the first metal layer 221 may be one or more of a tungsten (W) layer, a cobalt (Co) layer, a nickel (Ni) layer, a tantalum (Ta) layer, a tantalum nitride (TaN) layer, a titanium (Ti) layer, a titanium nitride (TiN) layer, etc. In some embodiments, the material of the first metal layer 221 may be titanium nitride, and the thickness of the first metal layer 221 may be 30-60 angstroms. For example, the thickness of the first metal layer 221 may be 30 angstroms, 40 angstroms, 50 angstroms or 60 angstroms.

In some embodiments, the material of the second metal layer 224 may be one or more of tungsten (W), cobalt (Co), nickel (Ni), tantalum (Ta), tantalum nitride (TaN), titanium (Ti), titanium nitride (TiN), etc. In some embodiments, the material of the second metal layer 224 may be tungsten (W), and the thickness of the W material may be 200-500 angstroms. For example, the thickness of the second metal layer 224 may be 200 angstroms, 300 angstroms, 400 angstroms or 500 angstroms.

In some embodiments, in order to reduce the interaction between the gate structure 200 and the first electrode 300, the fuse structure further includes an insulation structure 500, which is formed on the active area 110 and between the first electrode 300 and the gate structure 200.

Exemplarily, the insulating structure 500 includes an insulating material with an isolation function. For example, the insulating structure 500 may be made of one or more of insulating materials such as silicon nitride (Si₃N₄), silicon oxynitride (SiON) or silicon nitride carbide (SiCN). When the insulating structure 500 is a multi-layer structure, an air gap may be formed at the interlayer to improve the isolation effect. In addition, multiple layers of the insulating structure 500 may be made of different materials. For example, a first layer may be silicon nitride, a second layer may be silicon oxide and a third layer may be silicon nitride. In the embodiment, the insulating structure 500 may be a single-layer structure formed of silicon nitride.

In some embodiments, the insulating structure 500 is formed on an outside of the gate structure 200. When the second electrode 400 is formed, part of the insulating structure 500 is removed by etching to expose part of the side of the gate structure 200 so as to form the second electrode 400. The exposed side of the gate structure 200 may be the side of the gate structure 200 away from the first electrode 300.

In some embodiments, in order to reduce the contact resistance between the second electrode 400 and the gate structure 200, a first conductive layer 223 with a lower resistivity is used instead of the second conductive layer 222 of the gate structure 200 to contact the second electrode 400. Exemplarily, the gate material layer 220 includes the first conductive layer 223 and the second conductive layer 222. The material of the first conductive layer 223 may be cobalt silicide (CoSi₂). The first conductive layer 223 adjoins the second conductive layer 222 in a direction parallel to the substrate 100. The resistivity of the first conductive layer 223 is smaller than that of the second conductive layer 222. The first conductive layer 223 can reduce the resistance of the electrical path, and increase the current for breaking down, thereby reducing the difficulty in breaking down the fuse dielectric layer 210.

In some embodiments, the first conductive layer 223 adjoins the second electrode 400.

In some embodiments, in the direction parallel to the substrate 100, the first conductive layer 223 has a first width and the second conductive layer 222 has a second width. The first width is smaller than the second width.

In some embodiments, in order to reduce the contact resistance between the first electrode 300 and the active area 110, the fuse structure further includes a third conductive layer 130.

The material of the third conductive layer 130 is cobalt silicide. The third conductive layer 130 is formed between the active area 110 of the substrate 100 and the first electrode 300. The resistivity of the third conductive layer 130 is smaller than that of the first electrode 300.

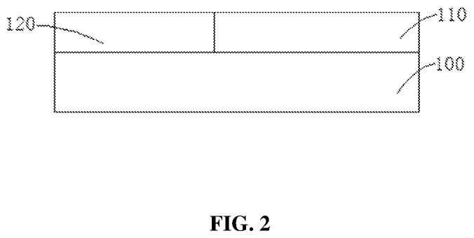

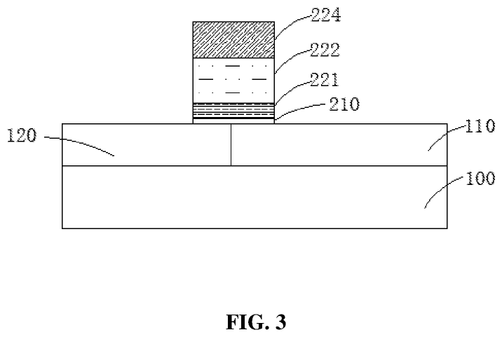

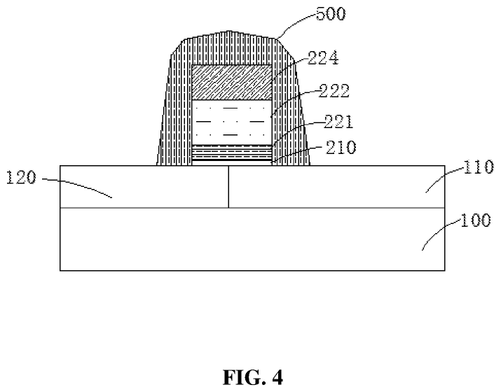

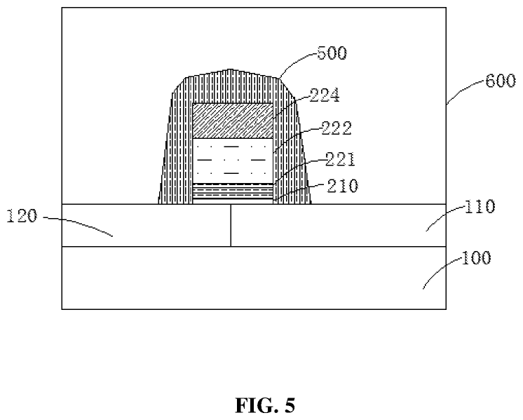

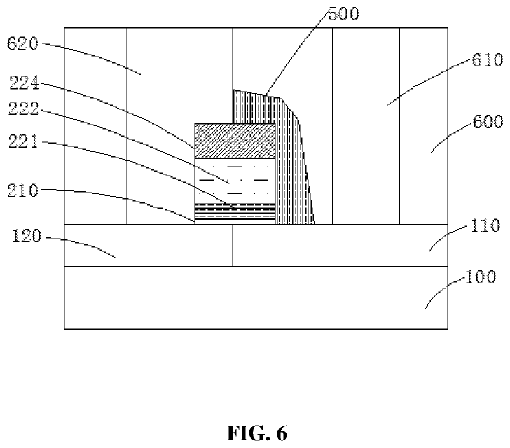

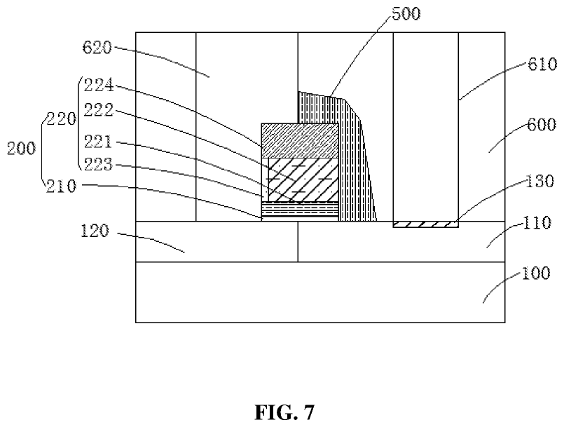

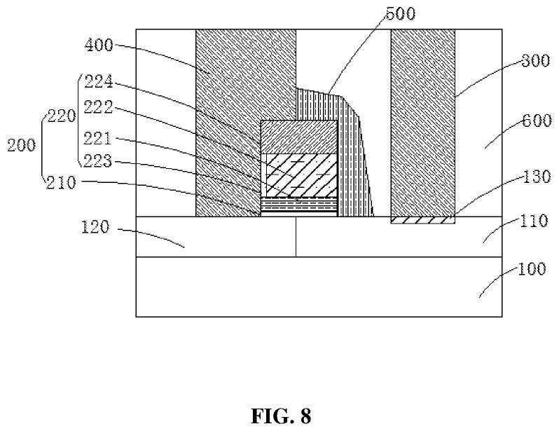

Referring to FIGS. 2-8, the embodiments of the present disclosure also provides a method for manufacturing a fuse structure, including the following operations.

A substrate 100 is provided, in which the substrate 100 includes an active area 110 and an isolation structure 120 adjoining the active area 110.

A gate structure 200 is formed, in which the gate structure 200 is at least partially formed on the active area 110.

A first electrode 300 is formed, in which the first electrode 300 is formed on the active area 110, and is spaced apart from the gate structure 200.

A second electrode 400 is formed, in which the second electrode 400 is at least partially formed on the isolation structure 120 and adjoins a side of the gate structure 200.

In the fuse structure of the embodiment, in a direction from the first electrode 300 to the second electrode 400, the first electrode 300, the active area 110, the gate structure 200 and the second electrode 400 are electrically connected in sequence to form an electrical path H. By connecting the second electrode 400 to the side of the gate structure 200, a contact area between the second electrode 400 and the gate structure 200 can be increased, which helps to reduce the conductive resistance, increasing the current in the electrical path H. As a result, it is easier to break down the fuse dielectric layer 210 in the gate structure 200.

In some embodiments, the substrate 100 may be a P-type silicon substrate or an N-type silicon substrate. In the embodiment, the substrate 100 is a P-type silicon substrate.

In some embodiments, the substrate 100 may be a monocrystalline silicon substrate or a polysilicon substrate. In the embodiment, the substrate 100 is a polysilicon substrate. The material of the active area 110 formed in the substrate 100 may be polysilicon.

In some embodiments, the material of the first electrode 300 and the second electrode 400 may be one or more of tungsten (W), cobalt (Co), nickel (Ni), tantalum (Ta), tantalum nitride (TaN), titanium (Ti), titanium nitride (TiN), etc. For example, the material of the first electrode 300 and the second electrode 400 each is titanium nitride.

In some embodiment, in order to reduce the interaction between the first electrode 300 and the second electrode 400, the fuse structure further includes a passivation layer 600.

The passivation layer 600 is formed between the first electrode 300 and the second electrode 400.

Exemplarily, the passivation layer 600 includes an insulating material with an isolation function. For example, the passivation layer 600 may be an oxide layer (BOX), and the material of the oxide layer may be silicon oxide (SiO₂).

In some embodiments, the isolation structure 120 may be an isolation structure 120 formed on the surface of the substrate 100 or a shallow trench isolation structure formed in the substrate 100.

Exemplarily, the second electrode 400 is formed on the isolation structure 120.

Exemplarily, the gate structure 200 is formed on both the active area 110 and the isolation structure 120.

In some embodiments, the gate structure 200 includes a fuse dielectric layer 210 and a gate material layer 220.

The fuse dielectric layer 210 is used for being broken down by a programming

current.

The gate material layer 220 is formed on the fuse dielectric layer 210.

Exemplarily, the fuse dielectric layer 210 of the gate structure 200 serves as a gate dielectric layer of the gate structure 200, and the material of the fuse dielectric layer 210 may be hafnium oxide (HfO₂). Adopting HfO₂ as the gate dielectric layer can allow the thickness of the gate dielectric layer to be smaller, thereby further reducing the difficulty in being broken down. In some embodiments, an equivalent thickness of HfO₂ may be less than 25 angstroms. For example, the equivalent thickness of the fuse dielectric layer 210 may be 15 angstroms, 16 angstroms, 17 angstroms, 18 angstroms, 19 angstroms or 20 angstroms, etc.

Exemplarily, the gate material layer 220 includes a second conductive layer 222, a first metal layer 221 and a second metal layer 224. The first metal layer 221 is provided between the second conductive layer 222 and the fuse dielectric layer 210, and the second metal layer 224 is provided between the second conductive layer 222 and the second electrode 400.

In some embodiments, the material of the second conductive layer 222 may be polysilicon, and the thickness of the second conductive layer 222 may be 300-700 angstroms. For example, the thickness of the dielectric layer 222 may be 300 angstroms, 400 angstroms, 500 angstroms, 600 angstroms or 700 angstroms.

In some embodiments, the first metal layer 221 may be one or more of a tungsten (W) layer, a cobalt (Co) layer, a nickel (Ni) layer, a tantalum (Ta) layer, a tantalum nitride (TaN) layer, a titanium (Ti) layer, a titanium nitride (TiN) layer, etc. In some embodiments, the material of the first metal layer 221 may be titanium nitride, and the thickness of the first metal layer 221 may be 30-60 angstroms. For example, the thickness of the first metal layer 221 may be 30 angstroms, 40 angstroms, 50 angstroms or 60 angstroms.

In some embodiments, the material of the second metal layer 224 may be one or more of tungsten (W), cobalt (Co), nickel (Ni), tantalum (Ta), tantalum nitride (TaN), titanium (Ti), titanium nitride (TiN), etc. In some embodiments, the material of the second metal layer 224 may be tungsten (W), and the thickness of the W material may be 200-500 angstroms. For example, the thickness of the second metal layer 224 may be 200 angstroms, 300 angstroms, 400 angstroms or 500 angstroms.

In some embodiments, forming the first electrode 300 includes the following operations.

The passivation layer 600 which covers the gate structure 200 is formed on the substrate 100.

A first electrode hole 300 is formed by etching in the passivation layer 600 on the active area 110, in which the first electrode hole 300 exposes the active area 110.

A first electrode 300 material is filled in the first electrode hole 300 to form the first electrode 300.

The passivation layer 600 includes an insulating material with an isolation function. For example, the passivation layer 600 may be the oxide layer (BOX), and the material of the oxide layer may be silicon oxide (SiO₂).

Exemplarily, the forming process of the first electrode hole 300 may be as follows.

A photoresist layer is formed on the passivation layer 600; the photoresist layer is patterned to form a first etching window; the passivation layer 600 is etched according to the first etching window to expose part of the active area 110 so as to form the first electrode hole 300; and the photoresist layer is removed.

In some embodiments, forming the second electrode 400 includes the following operations.

A second electrode hole 400 is formed in the passivation layer 600 on the isolation structure 120, in which the second electrode hole 400 exposes at least a side of the gate structure 200.

An electrode material is filled in the second electrode hole 400 to form the second electrode 400.

Exemplarily, the forming process of the second electrode hole 400 may be as follows.

A photoresist layer is formed on the passivation layer 600; the photoresist layer is patterned to form a first etching window and a second etching window; the passivation layer 600 and part of the barrier layer is etched according to the second etching window to expose at least part of a top surface of the gate structure 200 and the side thereof away from the first electrode 300 to form the second electrode hole 400; and the photoresist layer is removed.

In some embodiments, the method for forming a fuse structure further includes the following operation.

A first conductive layer 223 is formed. The first conductive layer 223 is formed on a side of the gate structure 200 adjoining the first electrode 300. The gate structure 200 includes the second conductive layer 222. The first conductive layer 223 adjoins the second conductive layer 222 in a direction parallel to the substrate 100. The resistivity of the first conductive layer 223 is smaller than that of the second conductive layer 222.

In some embodiments, forming the first conductive layer 223 includes the following operations

A metal is deposited in the second electrode hole 400 before the second electrode 400 is formed in the second electrode hole 400.

The polysilicon in the second conductive layer 222 exposed in the second electrode hole 400 is reacted with the metal by high temperature annealing to form the first conductive layer 223.

Exemplarily, the method for forming the first conductive layer 223 may be as follows.

A metal is deposited in the second electrode hole 400, in which the deposited metal may be a cobalt layer. An interdiffusion is caused between the polysilicon in the second conductive layer 222 and the cobalt layer by high temperature annealing to form cobalt silicide (CoSi₂, i.e. the first conductive layer 223).

In some embodiments, in the direction parallel to the substrate 100, the first conductive layer 223 has a first width and the second conductive layer 222 has a second width. The first width is smaller than the second width.

In some embodiments, the method for forming a fuse structure further includes the following operation

A third conductive layer 130 is formed. The third conductive layer 130 is formed at the surface of the active area 110 adjoining the first electrode 300.

In some embodiments, forming the third conductive layer 130 includes the following operations.

Before the electrode material is filled in the first electrode hole 300, a metal is deposited in the first electrode hole 300.

The polysilicon in the active area 110 exposed in the first electrode hole 300 is reacted with the metal by high-temperature annealing to form the third conductive layer 130. The resistivity of the third conductive layer 130 is smaller than that of the first electrode 300.

Exemplarily, the method for forming the first conductive layer 223 may include the following operations.

The metal is deposited in the first electrode hole 300, in which the deposited metal may be the cobalt layer. The interdiffusion is caused between the polysilicon in the active area 110 and the cobalt layer by high-temperature annealing to form cobalt silicide (CoSi₂, i.e. the third conductive layer 130).

In some embodiments, in order to reduce the interaction between the gate structure 200 and the first electrode 300, the method for forming a fuse structure further includes the following operation.

An insulating structure 500 is on an outside of the gate structure 200.

Exemplarily, the insulating structure 500 includes an insulating material with the isolation function. For example, the insulating structure 500 may be made of one or more of insulating materials such as silicon nitride (Si₃N₄), silicon oxynitride (SiON) or silicon nitride carbide (SiCN). When the insulating structure 500 has a multi-layer structure, an air gap may be formed at the interlayer to improve the isolation effect. In addition, multiple layers of the insulating structure 500 may be made of different materials. For example, a first layer may be silicon nitride, a second layer may be silicon oxide and a third layer may be silicon nitride. In the embodiment, the insulating structure 500 may be a single-layer structure made of silicon nitride.

In some embodiments, the insulating structure 500 is formed on the outside of the gate structure 200. When the second electrode 400 is formed, part of the insulating structure 500 is removed by etching to expose part of the side of the gate structure 200 to form the second electrode 400. The exposed side of the gate structure 200 may be the side of the gate structure 200 away from the first electrode 300.

An embodiment of the disclosure also provides a programmable memory including the fuse structure of anyone of the foregoing embodiments.

The programmable memory of this embodiment includes the fuse structure of anyone of the previous embodiments, and has the technical effect of the fuse structure, which will not be repeated here.

It will be understood that the above detailed description of the embodiments of the present disclosure is only used to illustrate or explain the principle of the embodiments of the present disclosure, and does not constitute a limitation on the embodiments of the present disclosure. Therefore, any modification, equivalent substitution, improvement, etc. made without departing from the spirit and scope of the embodiments of this disclosure shall fall within the protection scope of the embodiments of this disclosure. Furthermore, the appended claims of the embodiments of this disclosure are intended to cover all changes and modifications that fall within the scope and boundary of the appended claims, or the equivalent forms of such scope and boundary.

What is claimed is:

1. A fuse structure, comprising:
a gate structure, wherein the gate structure is at least partially formed on an active area of a substrate;
a first electrode, wherein the first electrode is formed on the active area of the substrate and is spaced apart from the gate structure;
a second electrode, wherein the second electrode is formed at least on a side of the gate structure; and
an isolation structure, wherein the isolation structure is formed between the active area and the second electrode.

2. The fuse structure of claim 1, wherein the gate structure comprises:
a fuse dielectric layer; and
a gate material layer, wherein the gate material layer is formed on the fuse dielectric layer.

3. The fuse structure according to claim 1, wherein
the isolation structure is formed in the substrate and adjoins the active area; and
the second electrode is formed on the isolation structure.

4. The fuse structure of claim 3, wherein the gate structure is formed on both the active area and the isolation structure.

5. The fuse structure of claim 1, further comprising: an insulating structure formed on the active area and between the first electrode and the gate structure.

6. The fuse structure of claim 2, wherein the gate material layer comprises a first conductive layer and a second conductive layer, wherein the first conductive layer adjoins the second conductive layer in a direction parallel to the substrate, and a resistivity of the first conductive layer is smaller than a resistivity of the second conductive layer.

7. The fuse structure of claim 6, wherein the first conductive layer adjoins the second electrode.

8. The fuse structure of claim 7, wherein the first conductive layer has a first width and the second conductive layer has a second width, in the direction parallel to the substrate, wherein the first width is smaller than the second width.

9. The fuse structure of claim 1, further comprising:
a third conductive layer, wherein the third conductive layer is formed between the active area of the substrate and the first electrode, and a resistivity of the third conductive layer is smaller than a resistivity of the first electrode.

10. The fuse structure of claim 1, further comprising:
a passivation layer, wherein the passivation layer is formed between the first electrode and the second electrode.

11. A method for forming a fuse structure, comprising:
providing a substrate, wherein the substrate comprises an active area and an isolation structure adjoining the active area;
forming a gate structure, wherein the gate structure is at least partially formed on the active area;
forming a first electrode, wherein the first electrode is formed on the active area, and is spaced apart from the gate structure; and
forming a second electrode, wherein the second electrode is at least partially formed on the isolation structure and adjoins a side of the gate structure.

12. The method according to claim 11, wherein the forming the first electrode comprises:
forming on the substrate a passivation layer covering the gate structure;
forming a first electrode hole in the passivation layer on the active area by etching, wherein the first electrode hole exposes the active area; and
filling a first electrode material in the first electrode hole to form the first electrode.

13. The method of claim 12, wherein the forming the second electrode comprises:
forming a second electrode hole in the passivation layer on the isolation structure, wherein the second electrode hole exposes at least the side of the gate structure; and
filling an electrode material in the second electrode hole to form the second electrode.

14. The method of claim 13, further comprising: before filling the electrode material in the second electrode hole,
forming a first conductive layer, wherein the first conductive layer is formed on a side of the gate structure adjoining the second electrode, and the gate structure comprises a second conductive layer, wherein the first conductive layer adjoins the second conductive layer in a direction parallel to the substrate, and a resistivity of the first conductive layer is smaller than a resistivity of the second conductive layer.

15. The method of claim 14, wherein the forming the first conductive layer comprises:
depositing a metal in the second electrode hole; and
reacting polysilicon in the second conductive layer exposed in the second electrode hole with the metal by high-temperature annealing to form the first conductive layer.

16. The method of claim 14, wherein the first conductive layer has a first width and the second conductive layer has a second width, in the direction parallel to the substrate, wherein the first width is smaller than the second width.

17. The method of claim 12, further comprising: before filling the first electrode material in the first electrode hole,
forming a third conductive layer, wherein the third conductive layer is formed at a surface of the active area adjoining the first electrode.

18. The method of claim 17, wherein the forming the third conductive layer comprises:
depositing a metal in the first electrode hole; and
reacting polysilicon in the active area exposed in the first electrode hole with the metal by high-temperature annealing to form the third conductive layer, wherein a resistivity of the third conductive layer is smaller than a resistivity of the first electrode.

19. The method of claim 11, further comprising:
forming an insulating structure on an outside of the gate structure.

20. A programmable memory, comprising the fuse structure according to claim 1.
